(19) United States
(12) Patent Application Publication
(10) Pub. No.: US 2025/0239535 A1
(43) Pub. Date: Jul. 24, 2025

(54) COMPONENT BUILT-IN WIRING BOARD AND METHOD FOR MANUFACTURING COMPONENT BUILT-IN WIRING BOARD

(71) Applicant: IBIDEN CO., LTD., Ogaki (JP)

(72) Inventors: Yuichi NAKAMURA, Ogaki (JP); Kazuki KAJIHARA, Ogaki (JP)

(73) Assignee: IBIDEN CO., LTD., Ogaki (JP)

(21) Appl. No.: 19/026,700

(22) Filed: Jan. 17, 2025

(30) Foreign Application Priority Data
Jan. 19, 2024 (JP) 2024-006862

(51) Int. Cl. H01L 23/538; H01L 23/00; H01L 23/13; H01L 23/14; H01L 23/29; H01L 23/31; H01L 25/07

(52) U.S. Cl. CPC H01L 23/5389; H01L 23/13; H01L 24/19; H01L 24/24; H01L 25/072; H01L 23/145; H01L 23/293; H01L 23/3121; H01L 24/25; H01L 2224/19; H01L 2224/2402; H01L 2224/24137; H01L 2224/2518

(57) ABSTRACT

A component built-in wiring board includes a core substrate having an opening, electronic components positioned in the opening of the substrate such that the electronic components are spaced apart with respect to each other, a build-up part formed on the substrate such that the build-up part is covering the electronic components in the opening of the substrate, and a resin part formed in the opening of the substrate and including a first resin part and a second resin part such that the second resin part is connecting the electronic components in the opening of the substrate and the first resin part is filling a space formed between the core substrate and the second resin part in the opening of the 10 substrate. The second resin part of the resin part is connecting the electronic components having different heights such that terminal surfaces of the electronic components are flush with each other.

### CROSS-REFERENCE TO RELATED APPLICATIONS

The present application is based upon and claims the benefit of priority to Japanese Patent Application No. 2024-006862, filed Jan. 19, 2024, the entire contents of which are incorporated herein by reference.

### BACKGROUND OF THE INVENTION

### Field of the Invention

The present invention relates to a component built-in wiring board and a method for manufacturing the component built-in wiring board.

### Description of Background Art

Japanese Patent Application Laid-Open Publication No. 2003-147049 describes a wiring board having a core substrate, multiple electronic components and a build-up part. The entire contents of this publication are incorporated herein by reference.

### SUMMARY OF THE INVENTION

According to one aspect of the present invention, a component built-in wiring board includes a core substrate having an opening portion, electronic components positioned in the opening portion of the core substrate such that the electronic components are spaced apart with respect to each other, a build-up part formed on the core substrate such that the build-up part is covering the electronic components in the opening portion of the core substrate, and a resin part formed in the opening portion of the core substrate and including a first resin part and a second resin part such that the second resin part is connecting the electronic components in the opening portion of the core substrate and that the first resin part is filling a space formed between the core substrate and the second resin part in the opening portion of the core substrate. The second resin part of the resin part is connecting the electronic components having different heights such that terminal surfaces of the electronic components are flush with respect to each other.

According to another aspect of the present invention, a method for manufacturing a component built-in wiring board includes preparing electronic components having different heights, inserting the electronic components into an opening portion of a core substrate from a terminal surface side of each of the electronic components, filling the opening portion of the core substrate with a first resin part such that the first resin part is formed in the opening portion of the core substrate, and forming a build-up part on the core substrate such that the build-up part covers the opening portion of the core substrate and is laminated on the core substrate. The preparing the electronic components includes connecting the electronic components to each other with a second resin part such that terminal surfaces of the electronic components are flush with respect to each other.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a cut-out portion of a component built-in wiring board according to an embodiment of the present invention;

FIG. 2 is a cross-sectional view illustrating a core insulating layer according to an embodiment of the present invention;

FIG. 3 is a cross-sectional view illustrating a state in which manufacture of a core substrate is started by providing an opening part in a core insulating layer according to an embodiment of the present invention;

FIG. 4 is a cross-sectional view showing a state in which a first component and a second component are positioned in the opening part according to an embodiment of the present invention;

FIG. 5 is a cross-sectional view illustrating a state in which a filling resin is filled in gaps in the opening part according to an embodiment of the present invention;

FIG. 6 is a cross-sectional view illustrating a state in which one interlayer insulating layer has been laminated as a build-up part on the core substrate according to an embodiment of the present invention;

FIG. 7A is a front view illustrating a state in which multiple sets of multiple electronic components are positioned on a sheet member according to an embodiment of the present invention;

FIG. 7B is a front view illustrating a state in which multiple electronic components are connected by a mold resin part according to an embodiment of the present invention; and

FIG. 7C is a front view illustrating a state in which connected multiple electronic components are divided into second manufacturing units according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

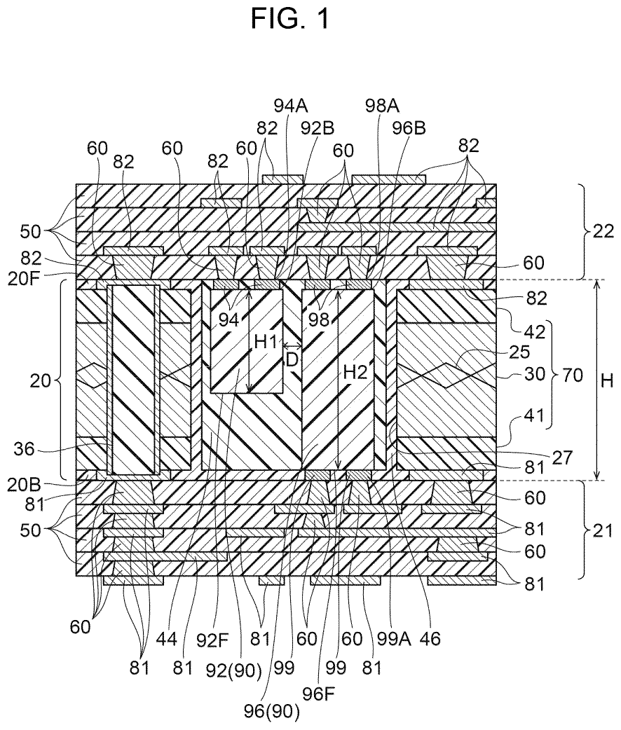

FIG. 1 is a cross-sectional view illustrating a portion of a component built-in wiring board 10 according to an embodiment of the present invention.

As illustrated in FIG. 1, the component built-in wiring board 10 of the present embodiment includes a core substrate 20 having a first surface (upper surface or front surface) (20F) and a second surface (lower surface or back surface) (20B) on an opposite side with respect to the first surface, a build-up part 22 formed on the first surface side of the core substrate 20, and a build-up part 21 formed on the second surface side of the core substrate 20.

Here, the upper surface or front surface refers to the upper side surface among the two surfaces of the core substrate 20 illustrated in the drawing, and the lower surface or back surface refers to the lower side surface among the two surfaces of the core substrate 20 illustrated in the drawing. Further, in the following description, in a thickness direction of the component built-in wiring board 10, for convenience, a side farther from the core insulating layer 70 is referred to as an “upper side,” an “upward direction,” or “upper,” and a side closer to the core insulating layer 70 is referred to as a “lower side,” a “downward direction,” or “lower.”

The build-up parts (21, 22) each have laminated multiple interlayer insulating layers 50, multiple conductor patterns (that is, lands) (81, 82) formed between the interlayer insulating layers 50, and multiple via conductors 60 formed to penetrate the interlayer insulating layers 50. The interlayer insulating layers 50 are each an example of an insulating layer.

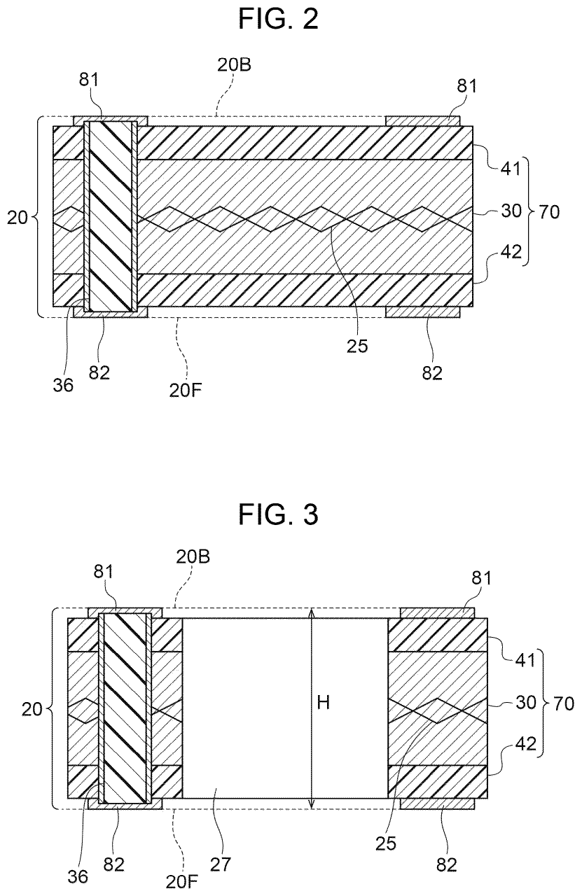

The core substrate 20 has a structure in which via conductors 60, through-hole conductors 36, conductor patterns (81, 82), and an opening part 27 are formed in the core insulating layer 70. That is, the core substrate 20 has the opening part 27. As illustrated in FIG. 2, the core insulating layer 70 is formed of an insulating substrate 30, and resin layers (41, 42) that are respectively formed on a first surface and a second surface on an opposite side with respect to the first surface of the insulating substrate 30. The resin layers (41, 42) are each formed using a thermosetting resin sheet, such as a prepreg. In the present embodiment, a reinforcing material 25 is contained in the insulating substrate 30 to ensure strength of the core substrate 20 as a whole. However, it is also possible that the reinforcing material 25 is not contained in the insulating substrate 30.

As illustrated in FIG. 1, the through-hole conductors 36 are each formed by forming a metal plating layer, such as a copper plating layer, on an inner wall of a through hole in the insulating substrate 30, filling an inner side thereof with a resin, and then applying cap plating to end surfaces thereof.

Then, the multiple conductor patterns (81, 82), which are conductor layers, are respectively formed on the resin layers (41, 42). These multiple conductor patterns (81, 82) are respectively formed by plating on the resin layer 42 formed on the first surface of the insulating substrate 30 and on the resin layer 41 formed on the second surface of the insulating substrate 30.

Via conductors 60 are respectively formed on an upper surface side and a back surface side of the through-hole conductors 36. These via conductors 60 are respectively formed by filling through holes formed in the resin layers (41, 42) with plating.

Then, a part of the conductor pattern 81 and a part of the conductor pattern 82 are electrically connected via the via conductors 60, the through-hole conductors 36, and conductor patterns (not illustrated in the drawings) on both sides of the insulating substrate 30.

As illustrated in FIGS. 1 and 3, the opening part 27 penetrates the core substrate 20 by a height (H) of the core substrate 20 from the first surface (20F) (upper surface of the resin layer 42) of the core substrate 20 to the second surface (20B) of the core substrate 20 (lower surface of the resin layer 41). Multiple electronic components 90 are inserted into the opening part 27. The opening part 27, into which the multiple electronic components 90 have been inserted, is filled with a molding resin and a filling resin, and when these resins solidify, a molding resin part 44 and a filling resin part 46 are respectively formed. The filling resin part 46 and the molding resin part 44 are respectively examples of a first resin part and a second resin part. The filling resin part 46 is formed of, for example, an epoxy resin as a filling resin. The upper and lower surfaces (the first surface (20F) and the second surface (20B)) of the core substrate 20 are respectively in contact with the interlayer insulating layers 50. The filling resin part 46 is formed of the same resin as the interlayer insulating layers 50 of the build-up parts (21, 22).

The multiple electronic components 90 include at least a first component 92 and a second component 96. The multiple electronic components 90 are, for example, passive components such as capacitors or inductors, or semiconductor devices.

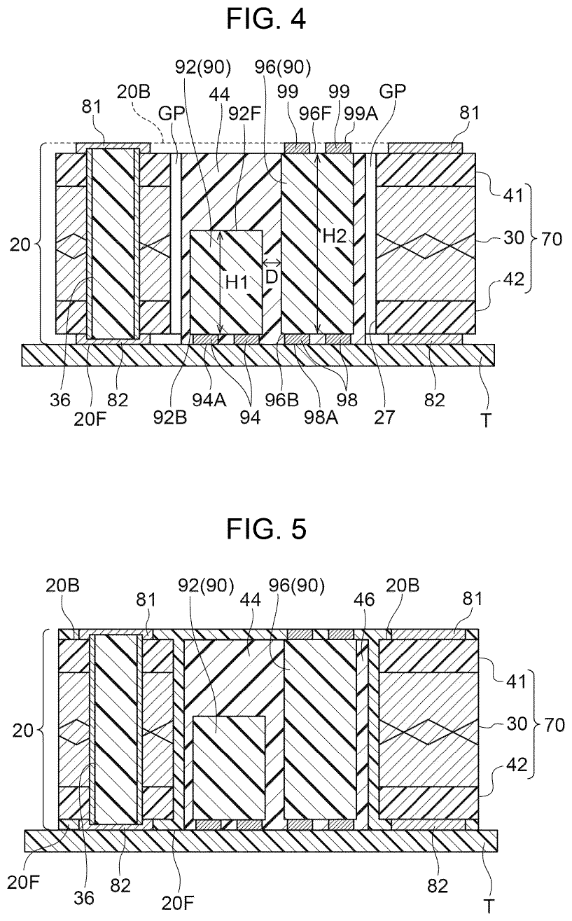

As illustrated in FIG. 4, the first component 92 has a box shape with a rectangular cross section and has a bottom surface (92B) and a top surface (92F), the top surface (92F) being positioned at a first height (H1) from the bottom surface (92B) and being formed along the bottom surface (92B). The top surface (92F) is a surface on an opposite side with respect to the bottom surface (92B). Further, a pair of terminals 94 protruding downward are positioned on the bottom surface (92B) of the first component 92, and there are no terminals formed on the top surface (92F). The terminals 94 are positioned to be flush with the first surface (20F) and are electrically connected to the via conductors 60.

The second component 96 has a box shape with a rectangular cross section and has a bottom surface (96B) and a top surface (96F), the top surface (96F) being positioned at a second height (H2) from the bottom surface (96B) and being formed along the bottom surface (96B). In the present embodiment, the second height (H2) is larger than the first height, that is, the first component 92 and the second component 96 have different heights. Further, the second height (H2) is less than a height (thickness) (H) of the core substrate, that is, it is a height that fits within the core substrate. Further, the second component 96 has a pair of terminals 98 protruding downward from the bottom surface 96B and a pair of terminals 99 protruding upward from the top surface (96F). In the present embodiment, a terminal surface (98A) of the terminals 98 is positioned to be flush with the first surface (20F) and the terminals 98 are electrically connected to the via conductors 60. Further, the terminals 99 are electrically connected to the via conductors 60 on the second surface (20B). In the present embodiment, a terminal surface (99A) of the terminals 99 is positioned to be flush with the second surface (20B). However, it is also possible that the terminal surface (99A) is not flush with the second surface (20B). However, even when the terminal surface (99A) is not flush with the second surface (20B), a structure in which the second height (H2) exceeds the height (H) of the core substrate 20 is excluded.

As illustrated in FIG. 4, the first component 92 and the second component 96 are spaced apart in a lateral direction by a gap (D) and are inserted into the opening part 27 in a state of being connected by a box-shaped molding resin part 44. In the lateral direction of the drawing, the molding resin part 44 is formed on a left side of the first component 92 (opposite side of the gap (D) with respect to the first component 92) and on a right side of the second component 96 (opposite side of the gap (D) with respect to the second component 96). That is, the left side of the first component 92 and the right side of the second component 96 are covered by the molding resin part 44. Although not illustrated, when viewed from an up-down direction, the molding resin part 44 is formed to surround the first component 92 and the second component 96. The first component 92 and the second component 96, connected by the molding resin part 44, are an example of connected electronic components. In the following, the multiple electronic components 90 connected by the molding resin part 44 may be simply referred to as “connected components 90.”

Next, a method for manufacturing the component built-in wiring board 10 of the present embodiment is described.

### Preparation of Multiple Electronic Components

First, the multiple electronic components 90 with different heights are prepared. Preparing the multiple electronic components 90 includes connecting the electronic components 90 with the molding resin part 44 such that the terminal surfaces thereof are flush with each other. Specifically, the multiple electronic components 90 are prepared in a state in which a terminal surface (94A) of the first component 92 and the terminal surface (98A) of the second component 96 are flush with each other and are connected by the molding resin part 44.

### Cavity Formation

As illustrated in FIG. 3, the opening part 27 is formed in the core substrate 20. Next, as illustrated in FIG. 4, an adhesive tape (T) is attached to an end surface of the conductor pattern 82 of the core substrate 20, with an adhesive surface facing the conductor pattern 82. Further, the connected components 90 are inserted into the opening part 27 from the terminal surface (94A) side and the terminal surface (98A) side, leaving defined gaps (GP) on both sides in the lateral direction in the drawing. When the connected components 90 are inserted into the opening part 27, the connected components 90 are flush with the adhesive surface of the adhesive tape (T).

As illustrated in FIG. 5, the gaps (GP) are filled with a filling resin. By solidifying the filling resin to form the filling resin part 46, the connected components 90 are fixed in the opening part 27. In the present embodiment, after forming the filling resin part 46 to a height above the second surface (20B) of the core substrate 20, the filling resin part 46 is polished down to the second surface (20B) (illustration omitted).

### Lamination of Build-Up Parts onto Core Substrate

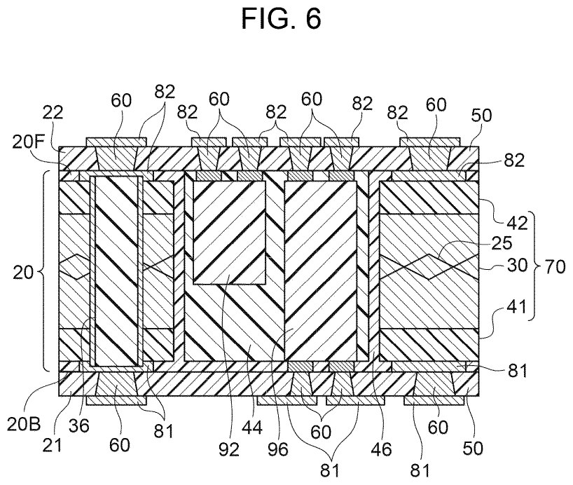

Next, the adhesive tape (T) is peeled off from the core substrate 20 in which the connected components 90 are fixed, and a core substrate 20 flipped upside down is prepared. FIG. 6 differs from FIGS. 2-5 in that the first surface (20F) and second surface (20B) are upside down. As illustrated in FIG. 6, one interlayer insulating layer 50 is laminated on the first surface (20F) and the second surface (20B) of the core substrate 20 and on the second component 96. After the lamination, the terminal surface (94A) of the first component 92 and the terminal surfaces (98A, 99A) of the second component 96 are respectively electrically connected to the via conductors 60. The via conductors 60 and the conductor patterns (81, 82) are integrally formed.

As described above, multiple interlayer insulating layers 50 are laminated according to product specifications. Finally, the multiple interlayer insulating layers 50 as the build-up parts (21, 22), together with the core substrate 20, form the component-embedded wiring board 10.

### Offline Processing of Multiple Electronic Components

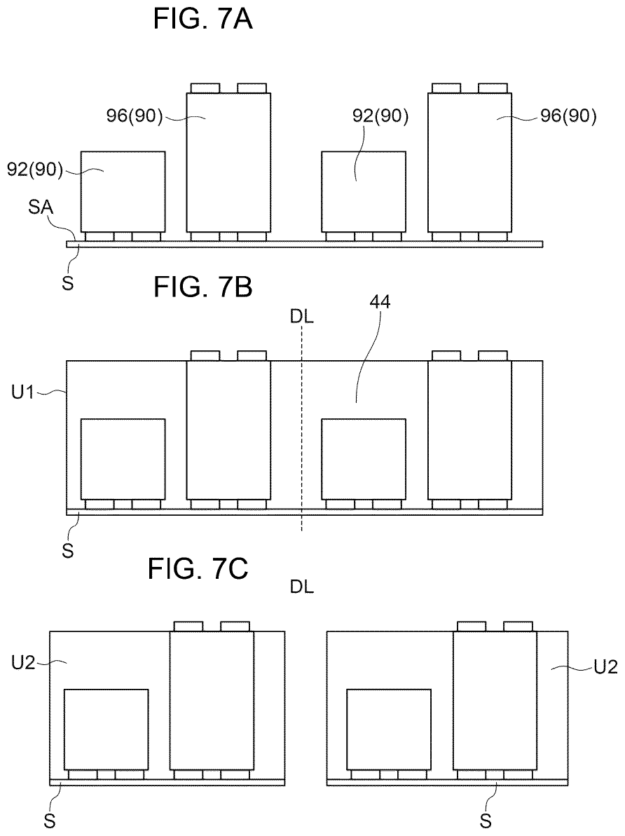

As illustrated in FIG. 7, the multiple electronic components 90 are connected prior to being inserted into the core substrate 20. In the present embodiment, the multiple electronic components 90 are connected in a separate manufacturing line (offline) from a manufacturing line of the core substrate 20. However, it is also possible that these manufacturing lines are the same.

As illustrated in FIG. 7A, multiple first components 92 and multiple second components 96, which are included in the multiple electronic components 90, are positioned on an upper surface (SA) of a sheet member(S) formed in a sheet shape (a double-sided tape attached to a substrate or wafer), such that the terminal surfaces (94A, 98A) are flush with each other. In the present embodiment, one first component 92 and one second component 96 are positioned with a gap (D) between them (refer to FIG. 4), and this one second component 96 and another first component 92 are positioned with a specified gap between them. That is, the first components 92 and the second components 96 are alternately positioned.

As illustrated in FIG. 7B, the multiple electronic components 90 positioned on the sheet member(S) are sealed with the molding resin part 44 as a first manufacturing unit (U1). The first manufacturing unit (U1) is an example of a first unit. The first manufacturing unit (U1) is determined by a dicing (singulation) position (DL). To seal the multiple electronic components 90, a mold frame (not illustrated) is provided on an outer side of the multiple electronic components 90, and the molding resin part 44 is formed by pouring liquid molding resin into the mold frame. An amount of the molding resin poured into the mold frame (not illustrated) is set to a level sufficient to connect the first components 92 and the second components 96. In the present embodiment, the molding resin is poured into the mold frame (not illustrated) to a level above the first height (H1) of the first components 92 and below the second height (H2) of the second components 96.

As illustrated in FIG. 7C, the first manufacturing unit (U1) is diced at the dicing position (DL) into second manufacturing units (U2), which are smaller than the first manufacturing unit (U1). The second manufacturing units (U2) are each an example of a second unit. By inserting connected components 90 after the dicing into the opening part 27 of the core substrate 20, the connected components 90 are used for manufacturing the component built-in wiring board 10. In the present embodiment, by peeling off the sheet member(S) from the connected components 90 and inserting the connected components 90 into the opening part 27, the connected components 90 are used for manufacturing the component built-in wiring board 10.

### Operation Effects

The component built-in wiring board 10 of the present embodiment includes the core substrate 20 having the opening part 27; the multiple electronic components 90 inserted into the opening part 27 in a state of being spaced apart from each other; the build-up parts (21, 22) formed on the core substrate 20 and the electronic components 90; and the filling resin part 46 that fills the opening part 27. The multiple electronic components 90 have different heights and are connected by the molding resin part 44 such that the terminal surfaces (94A, 98A) thereof are flush with each other. According to this structure, a space in the opening part 27 is occupied by the molding resin part 44 that connects the electronic components 90. Therefore, an amount of the filling resin filling the opening part 27 is reduced compared to a structure in which the multiple electronic components 90 are individually inserted into the opening part 27 and spaces between the electronic components 90 are filled with the filling resin part 46.

Next, in the component built-in wiring board 10 of the present embodiment, the multiple electronic components 90 include the first component 92 having the first height (H1) and the second component having the second height (H2) that is larger than the first height (H1). No terminals are formed on the top surface (92F) of the first component 92, while the terminals 99 are formed on the top surface (96F) of the second component. That is, the multiple electronic components 90 include the first component 92 and the second component 96. The first component 92 has the first height (H1) extending from the bottom surface (92B) to the top surface (92F) and has no terminals formed on the top surface (92F). The second component 96 has the second height (H2) extending from the bottom surface (96B) to the top surface (96F), where the second height (H2) is larger than the first height (H1), and has the terminals 99 formed on the top surface (96F). According to this structure, a connection failure between the core substrate 20 and the first component 92, which is lower in height than the second component 96, is avoided.

Then, in the component built-in wiring board 10 of the present embodiment, the build-up parts (21, 22) have the interlayer insulating layer 50 on the core substrate 20 side, and the filling resin part 46 is formed of the same resin as the interlayer insulating layer 50. Therefore, interlayer insulation is improved compared to a structure in which the filling resin part 46 is formed of a resin different from that of the interlayer insulating layers 50 in the build-up parts (21, 22).

Further, a method for manufacturing the component built-in wiring board 10 of the present embodiment includes: preparing the multiple electronic components 90 with differing heights; inserting the multiple electronic components 90 into the opening part 27 of the core substrate 20 from the terminal surface (94A) side of the first component 92 and the terminal surface (98A) side of the second component 96; filling the opening part 27 with the filling resin part 46; and laminating the build-up parts (21, 22) on the resin layers (41, 42) of the core substrate 20. Preparing the multiple electronic components 90 includes connecting the first component 92 and the second component 96 with the molding resin part 44 such that the terminal surface (94A) and the terminal surface (98A) are flush with each other. That is, as the multiple electronic components 90, the connected components 90 are prepared that are different in height in an insertion direction and are connected to each other by the molding resin part 44 such that the terminal surfaces (94A, 98A) are flush with each other. According to this manufacturing method, a space in the opening part 27 is occupied by the molding resin part 44 that connects the electronic components 90. Therefore, an amount of the filling resin filling the opening part 27 is reduced compared to a structure in which the multiple electronic components 90 are individually inserted into the opening part 27 and spaces between the electronic components 90 are filled with the filling resin part 46.

Then, in the method for manufacturing the component built-in wiring board 10 of the present embodiment, the build-up parts (21, 22) have the interlayer insulating layer 50 on the core substrate 20 side, and the filling resin part 46 is formed of the same resin as the interlayer insulating layer 50. According to this structure, interlayer insulation is improved compared to a structure in which the filling resin part 46 is formed of a resin different from that of the interlayer insulating layers 50 in the build-up parts (21, 22).

Further, in the method for manufacturing the component built-in wiring board 10 of the present embodiment, the multiple electronic components 90 are connected by the molding resin part 44 in the first manufacturing unit (U1), and the multiple electronic components 90 connected by the molding resin part 44 are separated into the second manufacturing unit (U2) smaller than the first manufacturing unit (U1). According to this manufacturing method, the multiple electronic components 90 connected by the molding resin part 44 are manufactured at once in the first manufacturing unit (U1).

### Modified Examples

### Terminals in Multiple Electronic Components

In the above description, the first component 92 is structured with no terminals formed on the top surface (92F). However, the present invention is not limited to this. It is also possible that terminals are formed on the top surface (92F) of the first component 92. In the above description, the second component 96 is structured with the terminals 99 formed on the top surface (96F). However, the present invention is not limited to this. It is also possible that no terminals are formed on the top surface (96F) of the second component 96.

### Resin of Build-Up Parts

In the above description, the filling resin part 46 is formed of the same resin as the interlayer insulating layers 50 of the build-up parts (21, 22). However, the present invention is not limited to this. It is also possible that the filling resin part 46 is formed of a different resin from that of the interlayer insulating layers 50 of the build-up parts (21, 22).

### First Manufacturing Unit

In the above description, the multiple electronic components 90 are sealed by the molding resin part 44 as the first manufacturing unit (U1) and then diced. However, the present invention is not limited to this. It is also possible that the first manufacturing unit (U1) is inserted into the core substrate 20 as it is.

### Molding Resin

In the above description, the molding resin part 44 is poured into a mold frame (not illustrated) to a level above the first height (H1) of the first component 92 and below the second height (H2) of the second component 96. However, the present invention is not limited to this. It is also possible that the molding resin part 44 is poured into the mold frame (not illustrated) to a level below the first height (H1) or above the second height (H2). Further, in the above description, the molding resin part 44 is poured into the mold frame (not illustrated). However, the present invention is not limited to this. It is also possible that a solid resin is formed around the multiple electronic components 90, and the first component 92 and the second component 96 are connected by heating. In the above description, the first component 92 and the second component 96 both have a box shape with a rectangular cross section. However, the present invention is not limited to this. It is also possible that the first component 92 and the second component 96 differ in size or shape, as long as they are connected by the molding resin part 44.

Japanese Patent Application Laid-Open Publication No. 2003-147049 describes a wiring board including a core substrate having an opening part; multiple electronic components positioned in the opening part with gaps between them in a state of being spaced apart from each other; and a build-up part formed on the core substrate and on the electronic components, wherein the gaps are filled with resin.

In a structure in which multiple electronic components are inserted into an opening part, a large amount of a first resin filling the opening part is required.

A component built-in wiring board according to an embodiment of the present invention includes a core substrate having an opening part; multiple electronic components inserted in a state of being spaced apart from each other in the opening part; a build-up part formed on the core substrate and on the electronic components; and a first resin part filling the opening part. The multiple electronic components have different heights and are connected by a second resin part such that terminal surfaces of the electronic components are flush with each other.

A method for manufacturing a component built-in wiring board according to an embodiment of the present invention includes preparing multiple electronic components with different heights; inserting the multiple electronic components into an opening part of a core substrate from a terminal surface side of each of the electronic components; filling the opening part with a first resin part; and laminating a build-up part on the core substrate. Preparing the multiple electronic components includes connecting the electronic components to each other with a second resin part such that terminal surfaces of the electronic components are flush with each other.

According to a component built-in wiring board and a method for manufacturing a component built-in wiring board according embodiments of the present invention, a space in the opening part is occupied by the second resin part that connects the electronic components to each other. Therefore, an amount of the first resin filling the opening part is reduced compared to a structure in which the multiple electronic components are individually inserted into the opening part and spaces between the electronic components is filled with the first resin part.

Obviously, numerous modifications and variations of the present invention are possible in light of the above teachings. It is therefore to be understood that within the scope of the appended claims, the invention may be practiced otherwise than as specifically described herein.

1. A component built-in wiring board, comprising:
a core substrate having an opening portion;
a plurality of electronic components positioned in the opening portion of the core substrate such that the electronic components are spaced apart with respect to each other;
a build-up part formed on the core substrate such that the build-up part is covering the electronic components in the opening portion of the core substrate; and
a resin part formed in the opening portion of the core substrate and comprising a first resin part and a second resin part such that the second resin part is connecting the electronic components in the opening portion of the core substrate and that the first resin part is filling a space formed between the core substrate and the second resin part in the opening portion of the core substrate,
wherein the second resin part of the resin part is connecting the electronic components having different heights such that terminal surfaces of the electronic components are flush with respect to each other.

2. The component built-in wiring board according to claim 1, wherein the plurality of electronic components includes a first component having a first height and a second component having a second height higher than the first height such that the first component has no terminals on a surface of the first component on an opposite side with respect to the terminal surface and that the second component has terminals on a surface of the second component on an opposite side with respect to the terminal surface.

3. The component built-in wiring board according to claim 1, wherein the build-up part has an insulating layer formed on the core substrate such that the insulating layer and the first resin part of the resin part are formed of a same resin.

4. The component built-in wiring board according to claim 2, wherein the build-up part has an insulating layer formed on the core substrate such that the insulating layer and the first resin part of the resin part are formed of a same resin.

5. The component built-in wiring board according to claim 1, wherein the build-up part includes a plurality of interlayer insulating layers, a plurality of conductor patterns and a plurality of via conductors.

6. The component built-in wiring board according to claim 2, wherein the build-up part includes a plurality of interlayer insulating layers, a plurality of conductor patterns and a plurality of via conductors.

7. The component built-in wiring board according to claim 3, wherein the build-up part includes a plurality of interlayer insulating layers, a plurality of conductor patterns and a plurality of via conductors.

8. The component built-in wiring board according to claim 4, wherein the build-up part includes a plurality of interlayer insulating layers, a plurality of conductor patterns and a plurality of via conductors.

9. The component built-in wiring board according to claim 1, wherein the plurality of electronic components includes at least one of a passive component and a semiconductor device.

10. The component built-in wiring board according to claim 1, wherein the build- up part includes a plurality of via conductors connected to the terminal surfaces of the electronic components.

11. The component built-in wiring board according to claim 1, wherein the build-up part has an insulating layer formed on the core substrate such that the insulating layer and the first resin part of the resin part include a same resin.

12. The component built-in wiring board according to claim 1, wherein the build-up part has an insulating layer formed on the core substrate such that the insulating layer and the first resin part of the resin part are formed of an epoxy resin material.

13. The component built-in wiring board according to claim 1, wherein the build-up part has an insulating layer formed on the core substrate such that the insulating layer and the first resin part of the resin part include an epoxy resin material.

14. The component built-in wiring board according to claim 1, wherein the core substate includes a reinforcing material.

15. The component built-in wiring board according to claim 1, wherein the plurality of electronic components is positioned in the opening portion of the core substrate such that the terminal surfaces of the electronic components are flush with respect to a surface of the core substate.

16. The component built-in wiring board according to claim 2, wherein the plurality of electronic components includes at least one of a passive component and a semiconductor device.

17. The component built-in wiring board according to claim 6, wherein the plurality of electronic components includes at least one of a passive component and a semiconductor device.

18. A method for manufacturing a component built-in wiring board, comprising:
preparing a plurality of electronic components having different heights;
inserting the plurality of electronic components into an opening portion of a core substrate from a terminal surface side of each of the electronic components;
filling the opening portion of the core substrate with a first resin part such that the first resin part is formed in the opening portion of the core substrate; and
forming a build-up part on the core substrate such that the build-up part covers the opening portion of the core substrate and is laminated on the core substrate,
wherein the preparing the plurality of electronic components includes connecting the electronic components to each other with a second resin part such that terminal surfaces of the electronic components are flush with respect to each other.

19. The method for manufacturing a component built-in wiring board according to claim 18, wherein the forming the build-up part includes forming an insulating layer on the core substrate such that the insulating layer and the first resin part of the resin part are formed of a same resin.

20. The method for manufacturing a component built-in wiring board according to claim 18, further comprising:
forming a first unit comprising a plurality of first unit electronic components such that the first unit electronic components are connected by the second resin part; and
separating the first unit electronic components connected by the second resin part into a plurality of second units that are smaller than the first unit such that the plurality of second units includes the plurality of electronic components connected by the second resin part.
